(19) United States
(12) Patent Application Publication
(10) Pub. No.: US 2021/0257127 A1
(43) Pub. Date: Aug. 19, 2021

(54) WIRE HARNESS

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Takeshi SHIMIZU, Yokkaichi-shi (JP); Hirotaka BABA, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 17/275,269

(22) PCT Filed: Sep. 10, 2019
(86) PCT No.: PCT/JP2019/035468

§ 371 Date: Mar. 11, 2021

(30) Foreign Application Priority Data
Sep. 25, 2018 (JP) 2018-178534

(51) Int. Cl. H01B 7/42; H02G 3/32; H01B 7/18; B60R 16/02

(52) U.S. Cl. CPC H01B 7/421; H02G 3/32; H02G 3/0481; B60R 16/0215; H01B 7/1875

(57) ABSTRACT

A wire harness including: a plurality of core wires; a tubular electromagnetic shield enclosing an outer circumference of the plurality of core wires; and an insulating sheath in which the plurality of core wires and the electromagnetic shield are collectively embedded, wherein the insulating sheath includes: a first covering that is filled between the plurality of core wires and the electromagnetic shield, that covers an outer circumferential surface of the plurality of core wires in intimate contact therewith, and that covers an inner circumferential surface of the electromagnetic shield in intimate contact therewith; and a second covering that covers an outer circumferential surface of the electromagnetic shield in intimate contact therewith.

### BACKGROUND

The present disclosure relates to a wire harness.

Conventionally, a wire harness used in a vehicle such as a hybrid vehicle or an electric vehicle is provided with wires for electrically connecting electrical devices such as a high-voltage battery and a high-voltage inverter (e.g., see JP 2016-54030A).

### SUMMARY

Incidentally, examples of electrical devices used in a vehicle such as a hybrid vehicle or an electric vehicle as described above include a high-voltage inverter and a high-voltage battery, and there are cases where a large current that is several hundreds of amperes in magnitude flows through a wire, for example. There is demand for improvement of the heat dissipation properties of a wire harness because, when a large current flows through a wire, the temperature of the wire is likely to increase due to an increase in the amount of heat generated by the wire.

An exemplary aspect of the disclosure provides a wire harness by which heat dissipation can be improved.

A wire harness according to an exemplary aspect includes: a plurality of core wires; a tubular electromagnetic shield enclosing an outer circumference of the plurality of core wires; and an insulating sheath in which the plurality of core wires and the electromagnetic shield are collectively embedded, wherein the insulating sheath includes: a first covering that is filled between the plurality of core wires and the electromagnetic shield, that covers an outer circumferential surface of the plurality of core wires in intimate contact therewith, and that covers an inner circumferential surface of the electromagnetic shield in intimate contact therewith; and a second covering that covers an outer circumferential surface of the electromagnetic shield in intimate contact therewith.

According to the wire harness of the present disclosure, it is possible to improve heat dissipation.

### BRIEF DESCRIPTION OF THE DRAWINGS

FIG. 1 is a schematic configuration diagram showing a wire harness of one embodiment.

FIG. 2 is a transverse cross-sectional view showing a wire harness of one embodiment.

FIG. 3 is a schematic cross-sectional view showing a wire harness of one embodiment.

FIG. 4 is a transverse cross-sectional view showing a wire harness of a modification.

FIG. 5 is a transverse cross-sectional view showing a wire harness of a modification.

### DETAILED DESCRIPTION OF EMBODIMENTS

The following describes one embodiment of a wire harness with reference to the attached drawings. Note that, in the drawings, some of the components may be exaggerated or simplified for the sake of description. Also, the dimensional ratio of some parts may differ from their actual ratio. Also, to facilitate understanding of the description, some members are illustrated with a satin pattern, instead of being hatched in the cross-sectional views.

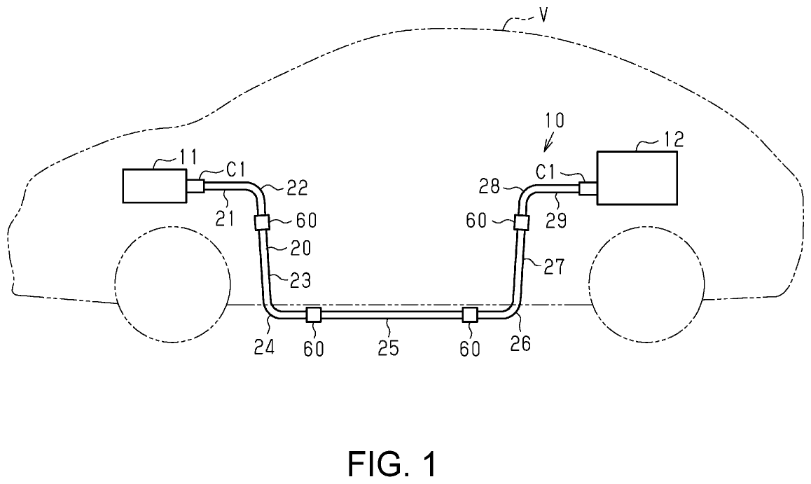

A wire harness 10 shown in FIG. 1 electrically connects two electric apparatuses (devices), or three or more electric apparatuses (devices). The wire harness 10 electrically connects an inverter 11 disposed in a front part of a vehicle V, such as a hybrid vehicle or an electric vehicle, and a high-voltage battery 12 disposed in a part of the vehicle V rearward of the inverter 11, for example. The wire harness 10 is routed under the floor of the vehicle, for example. The inverter 11 is connected to a wheel driving motor (not shown), which is a power source for driving the vehicle. The inverter 11 generates AC power from DC power that is supplied from the high-voltage battery 12, and supplies the AC power to the motor. The high-voltage battery 12 is a battery that can supply a voltage of several hundred volts, for example.

The wire harness 10 includes a wire 20, a pair of connectors Cl attached to opposite ends of the wire 20, and clamps 60 for fixing the wire 20 to the vehicle body of the vehicle V. The wire 20 is bendable two-dimensionally or three-dimensionally, for example. The wire 20 is bent into a predetermined shape according to the route where the wire harness 10 is to be routed, for example. The wire 20 in this embodiment includes a straight portion 21 extending from the connector Cl connected to the inverter 11 along the front-back direction of the vehicle, a bent portion 22 provided at an end portion of the straight portion 21, an extension portion 23 extending from the bent portion 22 toward a lower side of the vehicle, and a bent portion 24 provided at an end portion of the extension portion 23. The wire 20 in this embodiment includes a straight portion 25 extending from the bent portion 24 along the front-back direction of the vehicle, a bent portion 26 provided at an end portion of the straight portion 25, an extension portion 27 extending from the bent portion 26 toward an upper side of the vehicle, a bent portion 28 provided at an end portion of the extension portion 27, and a straight portion 29 extending from the bent portion 28 along the front-back direction of the vehicle.

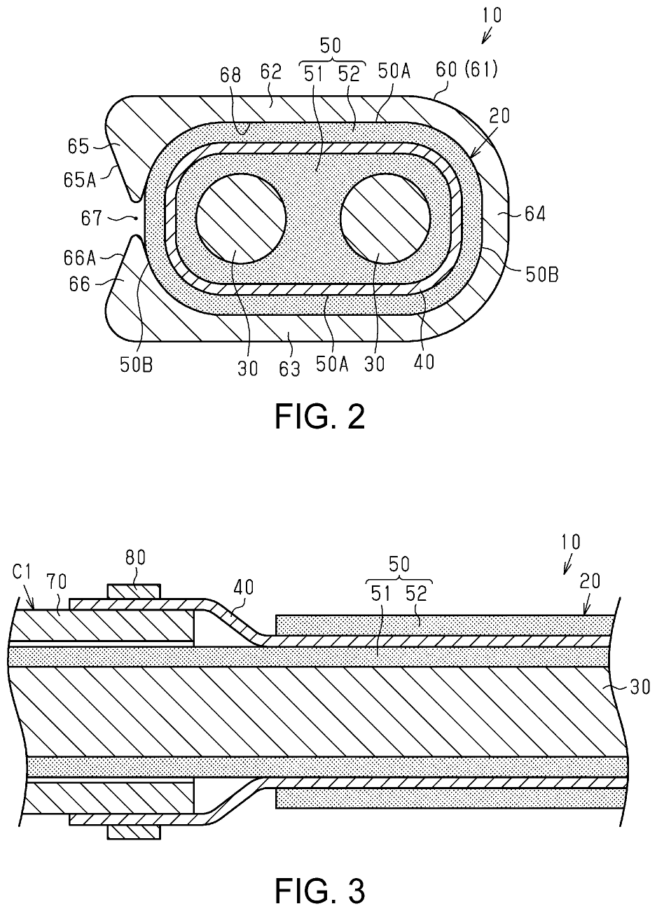

As shown in FIG. 2, the wire 20 includes a plurality (two in this embodiment) of core wires 30, a tubular electromagnetic shielding member 40 (tubular electromagnetic shield) enclosing an outer circumference of the core wires 30, and an insulating sheath 50 in which the plurality of core wires 30 and the electromagnetic shielding member 40 are collectively embedded.

The core wires 30 are elongated. The core wires 30 are flexible, and therefore are bendable into a shape extending along the route where the wire harness 10 is routed, for example. A twisted wire obtained by twisting a plurality of bare metal wires together, a columnar conductor (a single core wire, a bus bar, or the like) constituted by one columnar metal rod whose inside is solid, or a tubular conductor (a pipe conductor) whose inside is hollow can be used for the core wire 30, for example. A metallic material such as a copper-based material or an aluminum-based material can be used as the material of the core wire 30, for example. The core wires 30 are formed through extrusion molding, for example.

The transverse cross-sectional shape (i.e., a cross-sectional shape obtained by cutting a core wire 30 along a plane orthogonal to the length direction of the core wire 30) of each core wire 30 may be any shape and have any size. The transverse cross-sectional shape of each core wire 30 in this embodiment is a circular shape.

The plurality of core wires 30 are arranged side-by-side in the width direction of the vehicle (the left-right direction in FIG. 2), for example. The plurality of core wires 30 are spaced apart from each other. The insulating sheath 50 is formed between the plurality of core wires 30, and the core wires 30 are electrically insulated from each other.

The electromagnetic shielding member 40 has a tubular shape, and encloses the entire outer circumferences of the core wires 30. The electromagnetic shielding member 40 in this embodiment is formed to collectively enclose the plurality of core wires 30. However, the electromagnetic shielding member 40 is provided at a position spaced apart from the outer circumferential surfaces of the core wires 30. In other words, the electromagnetic shielding member 40 encloses the entire outer circumferences of the plurality of core wires 30 in a state in which the electromagnetic shielding member 40 is not in contact with the outer circumferential surfaces of the core wires 30.

The electromagnetic shielding member 40 has a flat tubular shape in which the inner and outer circumferences thereof have a flat cross-sectional shape, for example. In this specification, “flat shape” includes rectangular, oval, and elliptical shapes, for example. A “rectangular shape” in this specification has long sides and short sides, and does not include square shapes. Also, “rectangular shape” in this specification includes shapes obtained by chamfering a ridge portion and shapes obtained by rounding a ridge portion. The electromagnetic shielding member 40 in this embodiment has a rectangular tubular shape whose inner and outer circumferential cross-sectional shapes are rectangular. The electromagnetic shielding member 40 is provided over substantially the entire length of the core wires 30 in their length direction, for example.

It is possible to use a braided member in which a plurality of bare metal wires are brained into a tubular shape, or a metal film for the electromagnetic shielding member 40, for example. The electromagnetic shielding member 40 of this embodiment is a braided member. The electromagnetic shielding member 40 is more flexible than the core wires 30, for example. A metallic material such as a copper-based material or an aluminum-based material can be used as the material of the electromagnetic shielding member 40, for example.

The insulating sheath 50 has a covering portion 51 (first covering) that is filled between the plurality of core wires 30 and the electromagnetic shielding member 40, and a covering portion 52 (second covering) covering an outer circumferential surface of the electromagnetic shielding member 40 in intimate contact therewith. The covering portion 51 and the covering portion 52 are formed as a single body in the insulating sheath 50, for example. The insulating sheath 50 is made of an insulating material such as synthetic resin, for example. It is possible to use polypropylene, polyamide, or the like as the synthetic resin, for example. It is possible to use, as the material of the insulating sheath 50, curable resin such as photocurable resin or thermosetting resin, or curable resin in which multiple types of resins that are curable using different curing methods are mixed.

The insulating sheath 50 can be formed by performing, for example, extrusion molding (extrusion coating) on the core wires 30 and the electromagnetic shielding member 40. The covering portion 51 and the covering portion 52 are formed through extrusion molding performed in the same step simultaneously, for example.

The covering portion 51 covers the entire outer circumferential surface of each core wire 30 in intimate contact therewith. The covering portion 51 covers the entire inner circumferential surface of the electromagnetic shielding member 40 in intimate contact therewith. The covering portion 51 is formed such that a space between adjacent core wires 30 is filled with the covering portion 51. The covering portion 51 is formed such that a space between the outer circumferential surfaces of the core wires 30 and the inner circumferential surface of the electromagnetic shielding member 40 is filled with the covering portion 51. That is, the covering portion 51 is formed such that a space located inward of the inner circumferential surface of the electromagnetic shielding member 40 is filled with the covering portion 51. Thus, the transverse cross-sectional shape of the covering portion 51 of this embodiment is a rectangular shape. Note that the plurality of core wires 30 are embedded in the covering portion 51.

The covering portion 52 covers the entire inner circumferential surface of the electromagnetic shielding member 40 in intimate contact therewith.

Accordingly, the outer circumferential surface of the electromagnetic shielding member 40 is covered by the covering portion 52, and the inner circumferential surface of the electromagnetic shielding member 40 is covered by the covering portion 51. In other words, the electromagnetic shielding member 40 is embedded in the insulating sheath 50 (the covering portions 51 and 52).

The insulating sheath 50 (the covering portions 51 and 52) is formed to enter the mesh of the electromagnetic shielding member 40, for example. The insulating sheath 50 is formed such that the mesh of the electromagnetic shielding member 40 is filled with the insulating sheath 50, for example.

The outer circumferential cross-sectional shape of the insulating sheath 50 (the covering portion 52) may be any shape and have any size. The insulating sheath 50 (the covering portion 52) of this embodiment has a rectangular outer circumferential cross-sectional shape. The outer circumferential surface of the insulating sheath 50 includes a pair of long-side surfaces 50A that includes the long sides of the above-described rectangle, and a pair of side surfaces 50B that include the short sides of the rectangle.

In this embodiment, the insulating sheath 50 functions as a protective tube in the wire harness 10 as a result of using a photocurable resin or a thermosetting resin as the material of the insulating sheath 50. The insulating sheath 50 made of a photocurable resin is formed through extrusion molding or the like, and the insulating sheath 50 is irradiated with light (ultraviolet rays or the like), and thereby the hardness of the insulating sheath 50 can be increased, for example. Thus, the insulating sheath 50 with increased hardness can function as a protective tube for protecting the core wires 30 from flying objects and water droplets. Note that, if a thermosetting resin is used as the material of the insulating sheath 50, the heat-cured insulating sheath 50 can function as a protective tube in a similar manner.

If a photocurable resin or a thermosetting resin is used as the material of the insulating sheath 50, the wire 20 is bent to follow a wiring route shown in FIG. 1, and the insulating sheath 50 is cured through photocuring, heat-curing, or the like. It is possible to maintain the route where the wire 20 is routed, here, the wiring route that has the straight portions 21, 25, and 29, the bent portions 22, 24, 26, and 28, and the extension portions 23 and 27, through this curing. That is, the insulating sheath 50 in this case functions as a route-maintaining member for maintaining the route where the wire 20 is routed.

As shown in FIG. 2, the clamps 60 are attached to the outer circumferential surface of the insulating sheath 50 of the wire 20, for example. The clamps 60 each have a fitting portion 61 that is fitted to the outside of the insulating sheath 50, and a fixing portion (not shown) to be fixed to a vehicle body. A resin material or a metallic material can be used as the material of the clamps 60, for example. It is possible to use a conductive resin material or a resin material that has no conductivity as the resin material, for example. It is possible to use a metallic material such as an iron-based material or an aluminum-based material as the metallic material, for example.

The fitting portions 61 in this embodiment are substantially C-shaped.

That is, the fitting portions 61 have a discontinuous annular structure. The fitting portion 61 includes a pair of plate portions 62 and 63 that face each other, a connection portion 64 connecting one end portion of the plate portion 62 and one end portion of the plate portion 63, and locking portions 65 and 66 provided at the other end portions of the plate portions 62 and 63. The fitting portion 61 is a single component in which the plate portions 62 and 63, the connection portion 64, and the locking portions 65 and 66 are formed as a single body, for example.

The plate portions 62 and 63 each have an inner surface extending along the outer circumferential surface of the insulating sheath 50, for example. The plate portions 62 and 63 each have an inner surface extending along the long-side surfaces 50A of the insulating sheath 50.

The connection portion 64 connects an end portion of the plate portion 62 and an end portion of the plate portion 63. The connection portion 64 has an inner surface extending along the side surface 50B of the insulating sheath 50, for example.

The locking portions 65 and 66 are respectively provided at end portions of the plate portions 62 and 63 that are located opposite to the connection portion 64. That is, the locking portions 65 and 66 are provided at positions that are located opposite to the connection portion 64 in the long-side direction. The locking portion 65 extends from an end portion of the plate portion 62 toward the plate portion 63. The locking portion 66 extends from an end portion of the plate portion 63 toward the plate portion 62. A leading end portion of the locking portion 65 is provided at a position spaced apart from a leading end portion of the locking portion 66, facing the leading end portion of the locking portion 66. The fitting portion 61 is provided with an insertion portion 67 into which the wire 20 is insertable, due to the space located between the locking portions 65 and 66. An opening width of the insertion portion 67 is set shorter than the length of the side surface 50B of the insulating sheath 50 in the short-side direction. Also, the fitting portion 61 is provided with a housing portion 68 in which the wire 20 is housed in the space bounded by the inner surfaces of the plate portions 62 and 63, the inner surface of the connection portion 64, and the inner surfaces of the locking portions 65 and 66.

An outer surface of the locking portion 65 is an inclined surface 65A that is inclined toward the connection portion 64 when following the inclined surface 65A from a base end portion of the locking portion 65 (the end portion connected to the plate portion 62) toward its leading end portion (the end portion located opposite to the base end portion). An outer surface of the locking portion 66 is an inclined surface 66A that is inclined toward the connection portion 64 when following the inclined surface 66A from a base end portion of the locking portion 66 (the end portion connected to the plate portion 63) toward its leading end portion (the end portion located opposite to the base end portion). That is, the inclined surfaces 65A and 66A are inclined such that the opening width of the insertion portion 67 increases as the distance from the housing portion 68 increases.

The fitting portion 61 is configured to be deformable between a first orientation in which the wire 20 is insertable from the insertion portion 67 into the housing portion 68 and a second orientation in which the wire 20 inserted from the insertion portion 67 can be supported in the housing portion 68. That is, the fitting portion 61 is elastically deformable such that the gap between the locking portion 65 and the locking portion 66 (that is, the opening width of the insertion portion 67) increases. When the wire 20 is inserted into the insertion portion 67, for example, the fitting portion 61 elastically deforms such that the gap between the leading end portion of the locking portion 65 and the leading end portion of the locking portion 66 temporarily increases. Also, once the wire 20 passes through the insertion portion 67 and is fitted into the housing portion 68, the fitting portion 61 elastically returns such that the annular structure of the fitting portion 61 returns to the original shape, that is, the fitting portion 61 elastically returns such that the gap between the leading end portion of the locking portion 65 and the leading end portion of the locking portion 66 decreases. That is, the fitting portion 61 and the wire 20 in this embodiment form a snap-fit structure, using elastic deformation to prevent the wire 20 from coming off. Note that at least a portion of the inner surface of the fitting portion 61 is in contact with the outer circumferential surface of the insulating sheath 50 of the wire 20 in a state in which the wire 20 is housed in the housing portion 68.

The clamps 60 are fixed to a vehicle body by fixing portions (not shown). The wire 20 is fixed to the vehicle body by the clamps 60.

Next, the structure of end portions of the wire 20 will be described below with reference to FIG. 3. Here, the structure of end portions of the wire 20 at the inverter 11 (see FIG. 1) will be described.

An end portion of the wire 20 is inserted into a conductive tubular member 70 (conductive tube) of the connector Cl connected to the inverter 11 (see FIG. 1).

It is possible to use a metallic material such as an iron-based material or an aluminum-based material as the material of the tubular member 70, for example. The tubular member 70 may also be subjected to surface treatment such as tin plating or aluminum plating, in accordance with the types of constituent metals and usage environments. The tubular member 70 has a rectangular tubular shape whose inner and outer circumferential cross-sectional shapes are rectangular, for example.

At an end portion of the wire 20, the covering portion 52 of the insulating sheath 50 covering the outer circumferential surface of the electromagnetic shielding member 40 is removed, and the electromagnetic shielding member 40 is exposed from the insulating sheath 50. Also, the end portion of the wire 20 is inserted into the inner portion of the tubular member 70 in a state in which the plurality of core wires 30 are covered by the covering portion 51 of the insulating sheath 50. That is to say, only the plurality of core wires 30 and the covering portion 51 of the wire 20 are inserted into the inner portion of the tubular member 70. Note that the covering portion 52 can be removed by selectively removing a resin portion (the covering portion 52) using a laser or the like, for example. At this time, the insulating sheath 50 with which the mesh of the electromagnetic shielding member 40 is filled may be removed, or left.

An end portion of the electromagnetic shielding member 40 exposed from the insulating sheath 50 is drawn out to be spaced apart from the covering portion 51 (the insulating sheath 50) covering the outer circumference of the core wire 30. The end portion of the electromagnetic shielding member 40 is fixed to the outer circumferential surface of the tubular member 70. The end portion of the electromagnetic shielding member 40 is fitted to the outside of the tubular member 70, enclosing the entire circumference of the tubular member 70, for example. The electromagnetic shielding member 40 is fitted to the outside of the tubular member 70 to be in direct contact with the outer circumferential surface of the tubular member 70.

The end portion of the electromagnetic shielding member 40 is connected to the outer circumferential surface of the tubular member 70 by a crimping ring 80 provided on the outer circumferential side of the electromagnetic shielding member 40. The crimping ring 80 is fitted to the outside of the tubular member 70 in a state in which the end portion of the electromagnetic shielding member 40 is held between the outer circumferential surface of the tubular member 70 and the crimping ring 80. Also, when the crimping ring 80 is crimped, the end portion of the electromagnetic shielding member 40 is tightly fixed to the outer circumferential surface of the tubular member 70 in a state in which the end portion of the electromagnetic shielding member 40 is in direct contact with the outer circumferential surface of the tubular member 70. This ensures a stable electrical connection between the electromagnetic shielding member 40 and the tubular member 70.

Although the structure of end portions of the wire 20 at the inverter 11 shown in FIG. 1 has been described above, the same structure is provided to their end portions at the high-voltage battery 12.

Next, effects of this embodiment will be described below.

(1) The insulating sheath 50 is provided which has the covering portion 51 that is filled between the plurality of core wires 30 and the tubular electromagnetic shielding member 40 enclosing an outer circumference of the plurality of core wires 30, and the covering portion 52 that covers the outer circumferential surface of the electromagnetic shielding member 40 in intimate contact therewith. According to this configuration, because the covering portion 51 is filled between the core wires 30 and the electromagnetic shielding member 40, it is possible to inhibit an air layer, which is a heat insulating layer, from being interposed between the outer circumferential surfaces of the core wires 30 and the inner circumferential surface of the electromagnetic shielding member 40. Accordingly, the thermal resistance between the outer circumferential surfaces of the core wires 30 and the inner circumferential surface of the electromagnetic shielding member 40 can be reduced. Also, because the covering portion 52 covers the outer circumferential surface of the electromagnetic shielding member 40 in intimate contact therewith, it is possible to inhibit an air layer, which is a heat insulating layer, from being interposed between the electromagnetic shielding member 40 and the covering portion 52. Accordingly, the thermal resistance between the outer circumferential surface of the electromagnetic shielding member 40 and the inner circumferential surface of the covering portion 52 can be reduced. This inhibits heat generated by the core wires 30 from being trapped in the insulating sheath 50, and allows heat generated by the core wires 30 to be efficiently released from the outer circumferential surface of the insulating sheath 50 to the atmosphere. This makes it possible to efficiently release heat generated by the core wires 30 and to improve the heat dissipation properties of the wire harness 10. As a result, it is possible to keep the temperature of the wire 20 from increasing.

(2) The insulating sheath 50 is formed to collectively cover the plurality of core wires 30. Thus, it is possible to further reduce a gap between adjacent core wires 30, and to further reduce the size of the wire 20, compared to a case where a plurality of wires in which core wires are respectively covered by insulating sheaths are arranged side-by-side.

(3) A photocurable resin or a thermosetting resin is used as the material of the insulating sheath 50. This insulating sheath 50 functions as a protective tube in the wire harness 10. The insulating sheath 50 made of a photocurable resin is formed through extrusion molding or the like, and the insulating sheath 50 is irradiated with light (ultraviolet rays or the like), and thereby the hardness of the insulating sheath 50 can be increased, for example. Thus, the insulating sheath 50 with increased hardness can function as a protective tube for protecting the core wires 30 from flying objects and water droplets. Note that, if a thermosetting resin is used as the material of the insulating sheath 50, the heat-cured insulating sheath 50 can also function as a protective tube in a similar manner. As a result, it is possible to omit a protective tube, and to reduce the number of components. Furthermore, because the outer circumferential surface of the insulating sheath 50 is the outer surface of the wire harness 10, heat generated by the core wires 30 can be efficiently released from the outer circumferential surface of the insulating sheath 50 to the atmosphere.

(4) Also, after the wire 20 is bent to follow a desired wiring route, the insulating sheath 50 is cured through photocuring, heat-curing, or the like. Thus, because bending is performed on the wire 20 with greater flexibility than that once the insulating sheath 50 has been cured, the wire 20 can be bent with ease. On the other hand, the rigidity of the insulating sheath 50 can be increased through photocuring, heat-curing, or the like, and thus, the route where the wire 20 is routed can be maintained by the insulating sheath 50.

(5) The clamps 60 are attached to the outer circumferential surface of the insulating sheath 50 and fix the insulating sheath 50 to a vehicle body. According to this configuration, it is possible to efficiently transfer heat generated by the core wires 30 to the vehicle body with a large surface area through the insulating sheath 50 and the clamps 60. This makes it possible to efficiently release heat generated by the core wires 30 and to improve the heat dissipation properties of the wire harness 10.

(6) The electromagnetic shielding member 40 is formed to collectively enclose the plurality of core wires 30. According to this configuration, the electromagnetic shielding member 40 can be connected to the tubular member 70 through a single operation for the plurality of core wires 30, and thus the connection workability can be improved.

(7) At an end portion of the wire 20, the end portion of the electromagnetic shielding member 40 is exposed from the covering portion 52, and the exposed end portion of the electromagnetic shielding member 40 is connected to the outer circumferential surface of the tubular member 70 by the crimping ring 80. According to this configuration, even if the electromagnetic shielding member 40 is embedded in the inner portion of the insulating sheath 50, a stable electrical connection between the electromagnetic shielding member 40 and the tubular member 70 can be ensured by removing the covering portion 52 at the end portion of the electromagnetic shielding member 40.

### OTHER EMBODIMENTS

The above-described embodiment can be modified as follows. The embodiment described above and following modifications may be combined to the extent that they do not contradict each other technically.
The covering portion 51 and the covering portion 52 in the above-described embodiment need only be layered with the electromagnetic shielding member 40 held therebetween, and need not be formed simultaneously in the same step. The covering portion 51 for covering the outer circumference of the core wires 30 may be formed through extrusion molding, the electromagnetic shielding member 40 may be stacked on the outer circumferential surface of the covering portion 51, and then the covering portion 52 for covering the outer circumference of the electromagnetic shielding member 40 may be formed through extrusion molding, for example.
The covering portion 51 and the covering portion 52 in the above-described embodiment may be made of different resin materials. The covering portion 52 may be made of a curable resin such as a photocurable resin, and the covering portion 51 may be made of a resin material that is cheaper than the curable resin, for example. Even with such a configuration, the effects (3) and (4) of the above-described embodiment can be achieved because the covering portion 52 is made of a curable resin. Furthermore, a reduction in costs can be realized due to the covering portion 51 being made of an inexpensive resin material.
Although the electromagnetic shielding member 40 is provided to collectively enclose the outer circumferences of the plurality of core wires 30 in the above-described embodiment, there is no limitation thereto.

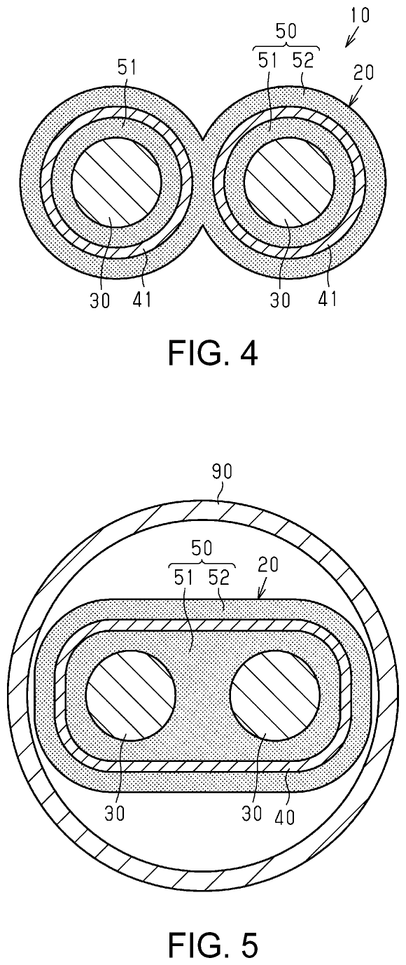

As shown in FIG. 4, for example, a configuration may be adopted in which a plurality of electromagnetic shielding members 41 for individually enclosing the plurality of core wires 30 are provided. That is to say, each electromagnetic shielding member 41 is provided to enclose the outer circumference of one core wire 30. The electromagnetic shielding member 41 has a tubular shape, and encloses the entire outer circumference of one core wire 30. The electromagnetic shielding member 41 is provided at a position spaced apart from the outer circumferential surface of the core wire 30. The plurality of electromagnetic shielding members 41 are spaced apart from each other, for example. A braided member or a metal film can be used as the electromagnetic shielding member 41, for example.

The covering portion 51 of the insulating sheath 50 in this case is formed such that the space between the outer circumferential surfaces of core wires 30 and the inner circumferential surfaces of the electromagnetic shielding members 41 is filled with the covering portion 51. Also, the covering portion 52 is formed to collectively enclose the outer circumferences of the plurality of electromagnetic shielding members 41. The transverse cross-sectional shape of the covering portion 52 has a shape extending along the outer circumferences of the core wires 30 and the electromagnetic shielding members 41, for example. Note that, similar to the covering portion 52 shown in FIG. 2, the transverse cross-sectional shape of the covering portion 52 may be a flat shape such as a rectangular shape.
Although the insulating sheath 50 is photocured or heat-cured over substantially the entire length thereof in the above-described embodiment, the insulating sheath 50 may be partially photocured or heat-cured. The insulating sheath 50 at the bent portions 22, 24, 26, and 28 of the wire 20 may be photocured or heat-cured, for example. In this case, the hardness of the insulating sheath 50 at the cured bent portions 22, 24, 26, and 28 is higher than that of the insulating sheath 50 at the other portions (i.e., the straight portions 21, 25, and 29 and the extension portions 23 and 27), for example. According to this configuration, the shape of the insulating sheath 50 (the wire 20) can be partially fixed.
Although the outer circumferential surface of the insulating sheath 50 of the wire 20 is configured to be the outer surface of the wire harness 10 in the above-described embodiment, there is no limitation thereto.

As shown in FIG. 5, a configuration may be adopted in which a protective tube 90 for enclosing the outer circumference of the insulating sheath 50 of the wire 20 is provided, for example. The protective tube 90 has an overall elongated tubular shape. The wire 20 is inserted into the inner portion of the protective tube 90. Metal pipes or resin pipes, corrugated tubes, waterproof rubber covers, or a combination thereof may be used for the protective tube 90, for example. A metallic material such as an aluminum-based material or a copper-based material can be used as the material of a metal pipe or a corrugated tube, for example. A conductive resin material or a resin material that has no conductivity can be used as the material of a resin pipe or a corrugated tube, for example. It is possible to use synthetic resin such as polyolefin, polyamide, polyester, or an ABS resin, for this resin material, for example.

At this time, with the wire 20, the outer circumferential surface of the electromagnetic shielding member 40 is covered by the covering portion 52 of the insulating sheath 50 in intimate contact therewith, and thus radiant heat from the electromagnetic shielding member 40 is blocked by the covering portion 52. That is to say, the covering portion 52 in this modification functions as a blocking member for blocking radiant heat from the electromagnetic shielding member 40. Thus, radiant heat from the electromagnetic shielding member 40 can be kept from being transferred to the protective tube 90. This can inhibit heat from being trapped in the protective tube 90.

Note that a clamp for fixing the protective tube 90 to the vehicle body is attached to the outer circumferential surface of the protective tube 90 in this modification.
Although the crimping ring 80 is used as a linking member for fixing the electromagnetic shielding member 40 to the outer circumferential surface of the tubular member 70 in the above-described embodiment, there is no limitation thereto. A metal band, or a cable tie or adhesive tape made of resin, or the like may also be used as a linking member, instead of the crimping ring 80, for example.
There is no particular limitation on the structure of the clamp 60 in the above-described embodiment. The structure of the clamp 60 may be changed to a structure in which the clamp 60 has a fitting portion for enclosing the entire circumference of the wire 20, for example.
The transverse cross-sectional shape of the core wire 30 in the above-described embodiment may be an oval, elliptical, rectangular, square, or semicircular shape.
Although the number of core wires 30 embedded in the insulating sheath 50 is two in the above-described embodiment, there is no limitation thereto. The number of core wires 30 can be changed in accordance with the specifications of a vehicle. The number of core wires 30 may be three or more, for example. Low-voltage electrical wires that connect a low-voltage battery and various low-voltage devices (e.g., a lamp and a car audio device) may be added as wires constituting the wire harness 10, for example.
The arrangement relationship between the inverter 11 and the high-voltage battery 12 in the vehicle is not limited to that in the above-described embodiment, and may be changed as appropriate in accordance with the configuration of the vehicle.
Although the inverter 11 and the high-voltage battery 12 are adopted as the electric apparatuses connected by the wire 20 in the above-described embodiment, there is no limitation to this. The present disclosure is also applicable to wires that connect the inverter 11 and a wheel driving motor, for example. That is, it can be applied to any component that electrically connects electric apparatuses installed in a vehicle.

The present disclosure encompasses the following implementation examples. Not for limitation but for assistance in understanding, the reference numerals of the representative components in the representative embodiment are provided.

[Appendix 1] In one or more implementation examples of this disclosure, the wire harness (10) may include a plurality of conductive core wires (30), a conductive tubular electromagnetic shielding member (40) that encloses the plurality of conductive core wires (30), and an inner insulating resin layer (51) that electrically insulates the plurality of conductive core wires (30) and the electromagnetic shielding member (40),

in which outer circumferential surfaces of the plurality of conductive core wires (30) may be separated by a gap from an inner circumferential surface of the electromagnetic shielding member (40) over the entire length or substantially the entire length of the plurality of conductive core wires (30),

the outer circumferential surfaces of the plurality of conductive core wires (30) may be separated from each other by a gap over the entire length or substantially the entire length of the plurality of conductive core wires (30), and

an empty space between the outer circumferential surfaces of the plurality of conductive core wires (30) and an empty space between the outer circumferential surfaces of the plurality of conductive core wires (30) and the inner circumferential surface of the electromagnetic shielding member (40) may be filled with or occupied by the inner insulating resin layer (51) over the entire length or substantially the entire length of the plurality of conductive core wires (30).

[Appendix 2] In one or more implementation examples of this disclosure, the inner insulating resin layer (51) is in intimate contact with the outer circumferential surfaces of the plurality of conductive core wires (30) and the inner circumferential surface of the electromagnetic shielding member (40) over the entire length or substantially the entire length of the plurality of conductive core wires (30).

[Appendix 3] In one or more implementation examples of this disclosure, the inner insulating resin layer (51) may be longer than the electromagnetic shielding member (40).

[Appendix 4] In one or more implementation examples of this disclosure, the inner insulating resin layer (51) may continuously extend over the entire length or substantially the entire length of the plurality of conductive core wires (30).

[Appendix 5] In one or more implementation examples of this disclosure, no air path that continuously extends over the entire length or substantially the entire length of the plurality of conductive core wires (30) is formed between the outer circumferential surfaces of the plurality of conductive core wires (30) and the inner circumferential surface of the inner insulating resin layer (51).

[Appendix 6] In one or more implementation examples of this disclosure, no air path that continuously extends over the entire length or substantially the entire length of the plurality of conductive core wires (30) is formed between the outer circumferential surface of the inner insulating resin layer (51) and the inner circumferential surface of the electromagnetic shielding member (40).

[Appendix 7] The wire harness (10) according to one or more implementation examples of this disclosure may further include an outer insulating resin layer (52) that encloses the electromagnetic shielding member (40) from the outside and is in intimate contact with the outer circumferential surface of the electromagnetic shielding member (40).

[Appendix 8] In one or more implementation examples of this disclosure, the outer insulating resin layer (52) may be shorter than the electromagnetic shielding member (40).

[Appendix 9] In one or more implementation examples of this disclosure, an insulating resin forming the inner insulating resin layer (51) and an insulating resin forming the outer insulating resin layer (52) may have the same composition.

[Appendix 10] In one or more implementation examples of this disclosure, the inner insulating resin layer (51) and/or the outer insulating resin layer (52) may be made of a curable resin.

[Appendix 11] The wire harness (10) according to one or more implementation examples of this disclosure may include one or more bent portions (22, 24, 26, and 28), in which the inner insulating resin layer (51) and/or the outer insulating resin layer (52) that corresponds at the one or more bent portions (22, 24, 26, and 28) may be cured such that the one or more bent portions (22, 24, 26, and 28) maintain a bent shape that conforms to a route where the wire harness (10) is routed.

[Appendix 12] In one or more implementation examples of this disclosure, the wire harness (10) may be routed in a wiring route that includes a straight portion and a bent portion, and be configured to electrically connect a plurality of electrical devices (11 and 12), in which the inner insulating resin layer (51) and the outer insulating resin layer (52) have bending rigidity that is set such that the plurality of conductive core wires (30) maintain a shape with a length that is matched to that of the wiring route.

[Appendix 13] In one or more implementation examples of this disclosure, the inner insulating resin layer (51) may be configured to suppress a change in a distance between the plurality of conductive core wires (30), and to suppress a change in a distance between each conductive core wire (30) and the electromagnetic shielding member (40).

[Appendix 14] In one or more implementation examples of this disclosure, the wire harness (10) may have a flat contour having a predetermined aspect ratio in a cross-sectional view of the wire harness (10).

[Appendix 15] In one or more implementation examples of this disclosure, the inner insulating resin layer (51) and the outer insulating resin layer (52) may be configured such that the wire harness (10) maintains the predetermined aspect ratio.

[Appendix 16] In one or more implementation examples of this disclosure, the electromagnetic shielding member (40) may be a braided member, and an insulating resin forming the inner insulating resin layer (51) and/or an insulating resin forming the outer insulating resin layer (52) may enter the mesh of the braided member.

[Appendix 17] In one or more implementation examples of this disclosure, the outer circumferential surface of the outer insulating resin layer (52) may form an outer surface of the wire harness (10).

[Appendix 18] In one or more implementation examples of this disclosure, the plurality of conductive core wires (30) may extend in parallel to each other without intersecting with each other.

[Appendix 19] In one or more implementation examples of this disclosure, the plurality of conductive core wires (30) may be a power supply line.

It will be apparent to those skilled in the art that the present disclosure may be embodied in other specific forms without departing from the technical concept of the present disclosure. Some of the components described in the embodiment (or one or more aspects thereof) may be omitted, or some of the components may be combined, for example. The scope of the present disclosure should be determined with reference to the appended claims, along with the full scope of equivalents to which such claims are entitled.

1. A wire harness comprising:
a plurality of core wires;
a tubular electromagnetic shield enclosing an outer circumference of the plurality of core wires; and
an insulating sheath in which the plurality of core wires and the electromagnetic shield are collectively embedded,
wherein the insulating sheath includes:
a first covering that is filled between the plurality of core wires and the electromagnetic shield, that covers an outer circumferential surface of the plurality of core wires in intimate contact therewith, and that covers an inner circumferential surface of the electromagnetic shield in intimate contact therewith; and
a second covering that covers an outer circumferential surface of the electromagnetic shield in intimate contact therewith.

2. The wire harness according to claim 1,
wherein the second covering is made of a photocurable resin or a thermosetting resin.

3. The wire harness according to claim 2, further comprising
a clamp that is attached to the outer circumferential surface of the insulating sheath and that is for fixing the insulating sheath to a vehicle body.

4. The wire harness according to claim 2,
wherein hardness of a bent portion of the insulating sheath is higher than that of another portion of the insulating sheath.

5. The wire harness according to claim 1, further comprising
a tubular protective tube enclosing an outer circumference of the insulating sheath.

6. The wire harness according to claim 1,
wherein the electromagnetic shield is formed to collectively enclose the plurality of core wires.

7. The wire harness according to claim 1,
wherein the electromagnetic shield includes a plurality of electromagnetic shields that individually enclose the plurality of core wires.

8. The wire harness according to claim 1, comprising
a conductive tube having an outer circumferential surface to which an end of the electromagnetic shield is connected, wherein:
at ends of the plurality of core wires, an end of the electromagnetic shield is exposed from the second covering, and the ends of the plurality of core wires are inserted into an inner portion of the tube in a state in which the ends of the plurality of core wires are covered by the first covering, and
the end of the electromagnetic shield that is exposed from the second covering is connected to the outer circumferential surface of the tube by a linking member.
